(19) United States
(12) Patent Application Publication
(10) Pub. No.: US 2026/0016670 A1
(43) Pub. Date: Jan. 15, 2026

(54) ADVANCED CATADIOPTRIC ARCHITECTURES FOR VIRTUAL REALITY SYSTEM

(71) Applicant: Samsung Display Co., Ltd., Yongin-si (KR)

(72) Inventors: Bharathwaj Appan Narasimhan, San Jose, CA (US); Hui Chen, Palo Alto, CA (US)

(21) Appl. No.: 18/916,378

(22) Filed: Oct. 15, 2024

Related U.S. Application Data
(60) Provisional application No. 63/671,627, filed on Jul. 15, 2024.

(51) Int. Cl. G02B 17/00; G02B 5/30; G02B 17/08; G06F 1/16

(52) U.S. Cl. CPC G02B 17/008; G02B 5/3025; G02B 17/08; G06F 1/163

(57) ABSTRACT

A catadioptric optical system including a first lens having a first curved surface; a reflective polarizer on the first curved surface of the first lens; a second lens having a curved surface facing the first lens and a substantially flat surface facing away from the first lens; a quarter waveplate on the substantially flat surface of the second lens; and a third lens.

### CROSS-REFERENCE TO RELATED APPLICATIONS

The present application claims priority to and the benefit of U.S. Provisional Application No. 63/671,627, filed July 15, 2024, the entire content of which is incorporated herein by reference.

### BACKGROUND

### 1. Field

The present disclosure relates to lenses and virtual reality/augmented reality systems.

### 2. Description of the Related Art

Virtual reality (VR) and augmented reality (AR) headsets are becoming increasingly popular for gaming, social media, and/or mobile computing, for example. Related art VR or AR headsets include a display device and optics configured to enlarge the image generated by the display device (i.e., the optics are configured to generate an enlarged virtual image). The VR/AR headset may include any suitable type of display, such as an LCD or OLED display (e.g., an OLED microdisplay or a μOLED). The configuration of the optics may vary depending on the type of display selected. The configuration of the optics governs the resolution of the virtual image, the field-of-view of the headset, the total track length (i.e., compactness) of the headset, and the eyebox (i.e., the area within which eye pupil movement does not cause big visual degradation). In general, increasing the track length increases the focal length and the resolution of the virtual image. Related art optical systems in AR/VR systems utilize only refraction to increase the focal length, which results in the AR/VR headset being bulky and cumbersome for the user to wear.

The above information disclosed in this Background section is only for enhancement of understanding of the background of the invention and therefore it may contain information that does not constitute prior art.

### SUMMARY

The present disclosure relates to various embodiments of a catadioptric optical system. In one embodiment, the catadioptric optical system includes a first lens having a first curved surface; a reflective polarizer on the first curved surface of the first lens; a second lens having a curved surface facing the first lens and a substantially flat surface facing away from the first lens; and a third lens. The second lens is between the first lens and the third lens.

The catadioptric optical system may also include a quarter waveplate on the substantially flat surface of the second lens.

The first lens, the second lens, and the third lens may be separable from each other.

The second lens and the third lens may be bonded together.

The first lens, the second lens, and the third lens may be bonded together.

The reflective polarizer may be laminated to the first lens.

The reflective polarizer may be coated on the first lens.

The first surface of the third lens may be substantially flat.

The first curved surface of the first lens may be convex and spherical.

The curved surface of the second lens may be concave and spherical or aspherical.

The first surface of the third lens may be convex.

The catadioptric optical system may also include a half-mirror coating on the second surface of the third lens facing away from the second lens.

The catadioptric optical system may also include an anti-reflective coating on at least one of the first curved surface of the first lens, the second curved surface of the first lens, the curved surface of the second lens, the substantially flat surface of the second lens, or the first surface of the third lens.

The present disclosure also relates to various embodiments of a virtual reality headset. In one embodiment, the virtual reality headset includes a display; a processor; a non-volatile memory device; and a catadioptric optical system including a first lens having a first curved surface; a reflective polarizer on the first curved surface of the first lens; a second lens having a curved surface facing the first lens and a substantially flat surface facing away from the first lens; a quarter waveplate on the substantially flat surface of the second lens; and a third lens.

The virtual reality headset may also include a headband or strap configured to secure the virtual reality headset to a user’s head.

The display may be an organic light emitting display.

The present disclosure also relates to various embodiments of a method of displaying virtual reality images. In one embodiment, the method includes generating an image with a digital display; and reflecting and refracting the image with a catadioptric optical system including a first lens having a first curved surface and a second curved surface; a reflective polarizer on the second curved surface of the first lens; a second lens having a curved surface facing the first lens and a substantially flat surface facing away from the first lens; a quarter waveplate on the substantially flat surface of the second lens; and a third lens.

This summary is provided to introduce a selection of features and concepts of embodiments of the present disclosure that are further described below in the detailed description. This summary is not intended to identify key or essential features of the claimed subject matter, nor is it intended to be used in limiting the scope of the claimed subject matter. One or more of the described features may be combined with one or more other described features to provide a workable system or method.

### BRIEF DESCRIPTION OF THE DRAWINGS

In the following section, the aspects of the subject matter disclosed herein will be described with reference to exemplary embodiments illustrated in the figures, in which:

FIGS. 1A-1B are a perspective view and a block diagram, respectively, of a virtual reality and/or augmented reality (VR/AR) system including a catadioptric lens system according to one embodiment of the present disclosure;

FIGS. 1C-1D are schematic views of a user’s pupil during use of the VR/AR system of FIGS. 1A-1B;

FIG. 2 is a side view of a catadioptric lens system according to one embodiment of the present disclosure;

FIG. 3 is a side view of a catadioptric lens system according to one embodiment of the present disclosure; and

FIG. 4 is a side view of a catadioptric lens system according to one embodiment of the present disclosure.

### DETAILED DESCRIPTION

The present disclosure relates to various embodiments of a catadioptric lens system and a virtual reality (VR) and/or augmented reality (AR) system including the catadioptric lens system. In one or more embodiments, the catadioptric lens system includes a reflective polarizer and a quarter waveplate that are on different surfaces of the lens system and are therefore not laminated together. The catadioptric lens systems of the present disclosure are configured to exhibit better optical performance, including higher transmission efficiency, greater compactness, improved aberration correction, greater polarization control, and better yield in mass production than related art lens systems. The catadioptric lens systems of the present disclosure are configured to both reflect and refract the image generated by the digital display, which results in higher resolution of the virtual image with a shorter track length compared to a related art optical system that utilizes only refraction.

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures(including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

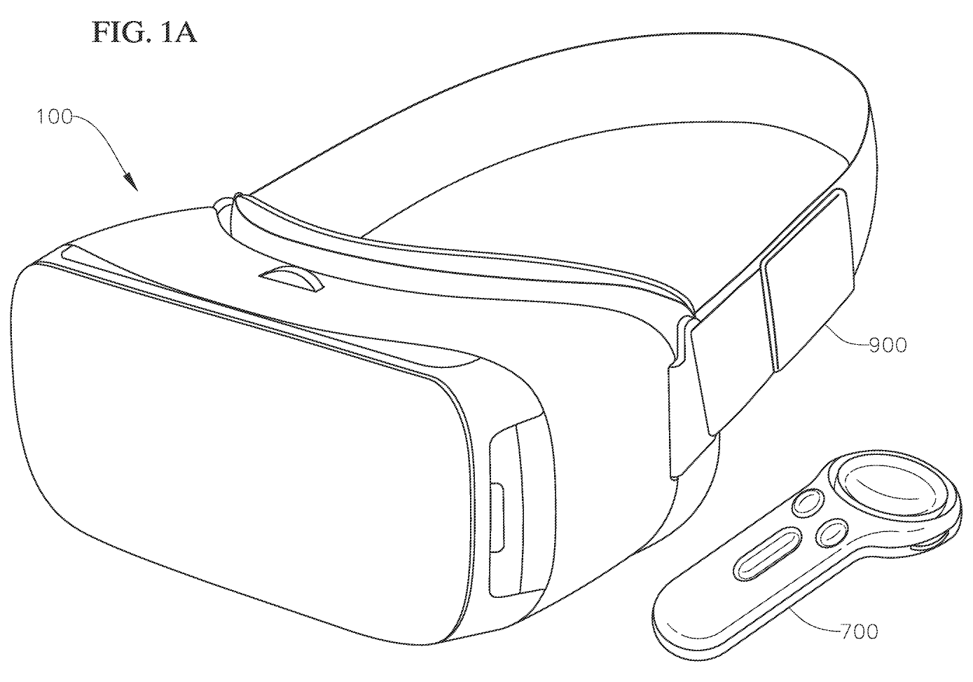

With reference now to FIGS. 1A-1B, a virtual reality and/or augmented reality (VR/AR) system 100 according to one embodiment of the present disclosure includes a digital display 200 (e.g., a digital micro-display, such as an organic light-emitting diode (OLED) display), and a catadioptric lens system 300 (i.e., viewing optics) in front of the digital display 200. When the VR/AR system 100 is worn by a user, the catadioptric lens system 300 is between the digital display 200 and the user’s eye. The catadioptric lens system 300 is configured to both reflect and refract the image generated by the digital display 200 to magnify the image generated by the digital display and thereby generate a virtual image. Utilizing both reflection and refraction results in a higher resolution of the virtual image with a shorter track length compared to a related art optical system that utilizes only refraction.

In one or more embodiments, the VR/AR system 100 also includes a processor 400 coupled to the digital display 200, a non-volatile memory device 500 (e.g., flash memory, ferroelectric random-access memory (F-RAM), magnetostrictive RAM (MRAM), FeFET memory, and/or resistive RAM (ReRAM) memory) coupled to the processor 400, and a power supply 600 (e.g., one or more secondary batteries) coupled to the processor 400. The non-volatile memory device 500 includes executable instructions (i.e., computer-readable code) which, when executed by the processor 400, cause the processor 400 to control the display of various images by the display 200. In one or more embodiments, the VR/AR system 100 may include an input device 700 (e.g., a handheld controller) configured to perform various operations, such as modifying the images displayed by the display 200. In one or more embodiments, the VR/AR system 100 may include a communication module (e.g., a network adapter) 800 configured to support establishing a direct (e.g., wired) communication channel or a wireless communication channel between the VR/AR system 100 and an external electronic device (e.g., another electronic device or a server) and performing communication via the established communication channel. In one or more embodiments, the VR/AR system 100 also includes a headband or strap 900 (e.g., an adjustable band) configured to secure the VR/AR system 100 to a user’s head.

The term “processor” is used herein to include any combination of hardware, firmware, and/or software, employed to process data or digital signals. The hardware of a processor may include, for example, application specific integrated circuits (ASICs), general purpose or special purpose central processors (CPUs), digital signal processors (DSPs), graphics processors (GPUs), and programmable logic devices such as field programmable gate arrays (FPGAs). In a processor, as used herein, each function is performed either by hardware configured, i.e., hard-wired, to perform that function, or by more general purpose hardware, such as a CPU, configured to execute instructions stored in a non-transitory storage medium. A processor may be fabricated on a single printed wiring board (PWB) or distributed over several interconnected PWBs. A processor may contain other processors; for example, a processor may include two processors, an FPGA and a CPU, interconnected on a PWB. The processor 400 may include a main processor (e.g., a central processing unit (CPU) or an application processor (AP)), and an auxiliary processor (e.g., a graphics processing unit (GPU), an image signal processor (ISP), a sensor hub processor, or a communication processor (CP)) that is operable independently from, or in conjunction with, the main processor. Additionally or alternatively, the auxiliary processor may be adapted to consume less power than the main processor, or execute a particular function. The auxiliary processor may be implemented as being separate from, or a part of, the main processor. The auxiliary processor may control at least some of the functions or states related to at least one component among the components of the electronic device, instead of the main processor while the main processor is in an inactive (e.g., sleep) state, or together with the main processor while the main processor is in an active state (e.g., executing an application). The auxiliary processor (e.g., an image signal processor or a communication processor) may be implemented as part of another component functionally related to the auxiliary processor.

The communication module 800 may include one or more communication processors that are operable independently from the processor 400 (e.g., the AP) and supports a direct (e.g., wired) communication or a wireless communication with another device. The communication module 800 may include a wireless communication module (e.g., a cellular communication module, a short-range wireless communication module, or a global navigation satellite system (GNSS) communication module) or a wired communication module (e.g., a local area network (LAN) communication module or a power line communication (PLC) module). A corresponding one of these communication modules may communicate with the external electronic device or a server via a short-range communication network (e.g., BLUETOOTH^{TM}, wireless-fidelity (Wi-Fi) direct, or a standard of the Infrared Data Association (IrDA)) or a long-range communication network (e.g., a cellular network, the Internet, or a computer network (e.g., LAN or wide area network (WAN)). These various types of communication modules may be implemented as a single component (e.g., a single IC), or may be implemented as multiple components (e.g., multiple ICs) that are separate from each other. The communication module 800 may identify and authenticate the VR/AR system 100 in a communication network, such as the short-range communication network or the long-range communication network, using subscriber information (e.g., international mobile subscriber identity (IMSI)) stored in a subscriber identification module. In one or more embodiments, the communication module 800 may include an antenna configured to transmit or receive a signal and/or power to or from the outside (e.g., an external electronic device) of the VR/AR system 100. In one or more embodiments, the communication module 800 may include one or more antennas, and, therefrom, at least one antenna appropriate for a communication scheme used in the communication network, such as the long-range or the short-range communication network, may be selected, for example, by the communication module 800. The signal or the power may then be transmitted or received between the communication module 800 and the external electronic device via the selected at least one antenna.

Commands or data may be transmitted or received between the VR/AR system 100 and an external electronic device via a server coupled with a long-range communication network. Each of the electronic devices may be a device of a same type as, or a different type, from the VR/AR system 100. All or some of operations to be executed at the VR/AR system 100 be executed at one or more of the external electronic devices. For example, if the VR/AR system 100 should perform a function or a service automatically, or in response to a request from a user or another device, the VR/AR system 100, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the VR/AR system 100. The VR/AR system 100 may provide the outcome, with or without further processing of the outcome, as at least part of a reply to the request. To that end, a cloud computing, distributed computing, or client-server computing technology may be used, for example.

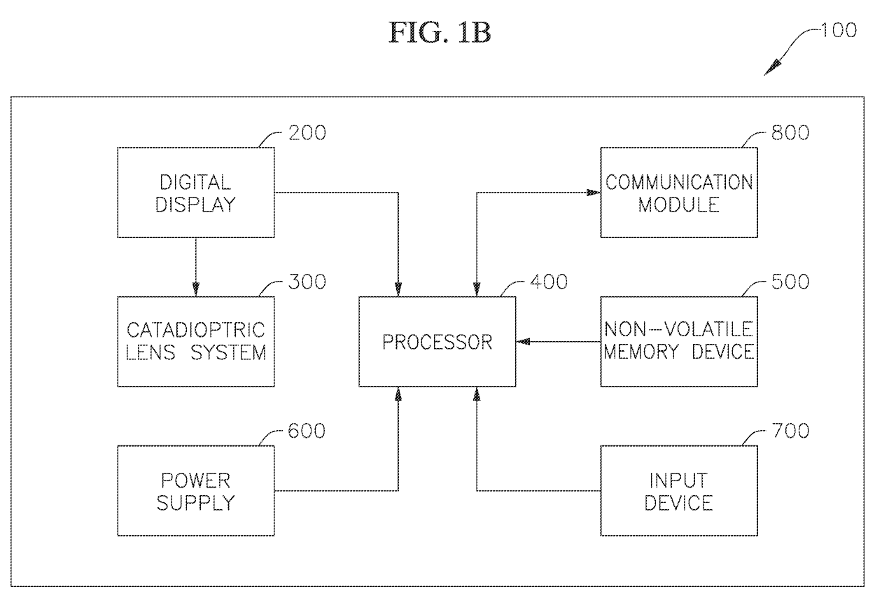

With reference now to FIG. 2, the catadioptric lens system 300 according to one embodiment of the present disclosure includes a first lens 301, a second lens 302, a third lens 303, a reflective polarizer 304, and a quarter wave plate 305. In the illustrated embodiment, the digital display 200 includes a circular polarizer 201 facing the catadioptric lens system (i.e., the circular polarizer 201 faces the third lens 303). The circular polarizer 201 is configured to circularly polarize the light emitted from the digital display 200. The quarter wave plate 305 is formed of a birefringent material (e.g., quartz, mica, and/or plastic) that is configured to alter the polarization state of a light wave passing through it (e.g., the quarter wave plate 305 is configured shift the phase of the incident light wave between two perpendicular polarization components, such as turning the circularly polarized light emitted from the circular polarizer 201 into linearly polarized light). The reflective polarizer 304 is configured to transmit a light wave having the desired polarization and to reflect the remainder of the light wave (i.e., the light wave not having the desired polarization).

In the illustrated embodiment, the second lens 302 is between the first lens 301 and the third lens 303. Additionally, in the illustrated embodiment, the first lens 301 includes a surface 306 facing away from the second lens 302 and a curved surface 307 facing the second lens 302. In one or more embodiments, the surface 306 of the first lens 301 is aspherical and the curved surface 307 of the first lens 301 is spherical.

The second lens 302 includes a curved surface 308 facing the first lens 301 and a flat (or substantially flat) surface 309 facing away from the first lens 301 and toward the third lens 303. In one or more embodiments, the curved surface 308 of the second lens 302 is concave and may be aspherical or spherical.

The third lens 303 includes a first curved surface 310 facing the second lens 302 and a second curved surface 311 facing away from the second lens 302. In one or more embodiments, the first curved surface 310 of the third lens 303 is convex and aspherical, and the second curved surface 311 of the third lens 303 is convex and aspherical. Additionally, in one or more embodiments, the catadioptric lens system 300 includes a half-mirror coating 312 on the second curved surface 311 of the third lens 303 and an anti-reflective (AR) coating on the surface 306 of the first lens 301, the curved surface 307 of the first lens 301, the curved surface 308 of the second lens 302, the flat (or substantially flat) surface 309 of the second lens 302, and the first curved surface 310 of the third lens 303.

In the illustrated embodiment, the reflective polarizer 304 is laminated on the curved surface 307 of the first lens 301, and the quarter wave plate 305 is laminated on the flat surface 309 of the second lens 302. Accordingly, the reflective polarizer 304 and the quarter wave plate 305 are on two different surfaces (e.g., surfaces that face away from each other). Thus, the reflective polarizer 304 and the quarter wave plate 305 are separate and separated from each other by the second lens 302. Providing the reflective polarizer 304 and the quarter wave plate 305 on two different surfaces is configured to improve performance and efficiency of the catadioptric lens system 300. Additionally, in the illustrated embodiment, the first lens 301, the second lens 302, and the third lens 303 are separate from each other (e.g., the first lens 301, the second lens 302, and the third lens 303 are not bonded or otherwise connected to each other).

FIG. 1C depicts a user’s pupil during operation of the VR/AR system 100. During operation of the VR/AR system 100, the image generated by the digital display 200 passes through the third lens 303 and then the quarter wave plate 305 on the flat surface 309 of the second lens 302, which alters the polarization state of the image generated by the digital display 200. The image having the altered polarization state is then incident on the reflective polarizer 304, which transmits the portion of the image having the desired polarization state to the first lens 301 and reflects the remaining portion of the image back through the second and third lenses 302, 303. The portion of the image passing through the first lens 301 is then visible by the user as an enlarged virtual image. In this manner, the catadioptric lens system 300 utilizes both reflection and refraction to generate the enlarged virtual image.

FIG. 1D depicts movement of a user’s pupil during operation of the VR/AR system 100. As shown in FIG. 1D, the catadioptric lens system 300 is configured such that the user’s pupil remains with the eyebox, which is the area within which the eye pupil movement does not cause significant visual degradation. In one or more embodiments, the eyebox may have a diameter of approximately 8 mm and the pupil may have a diameter of approximately 4 mm. Systems and methods configured to ensure adequate visual performance even with pupil misalignment, including applying weights to different pupil locations based on the probably of their occurrences (e.g., applying higher weights for on-axis locations than off-axis locations) and optimizing the design, are disclosed in U.S. Patent Application No. 18/658,700, filed on May 8, 2024, the entire content of which is incorporated herein by reference.

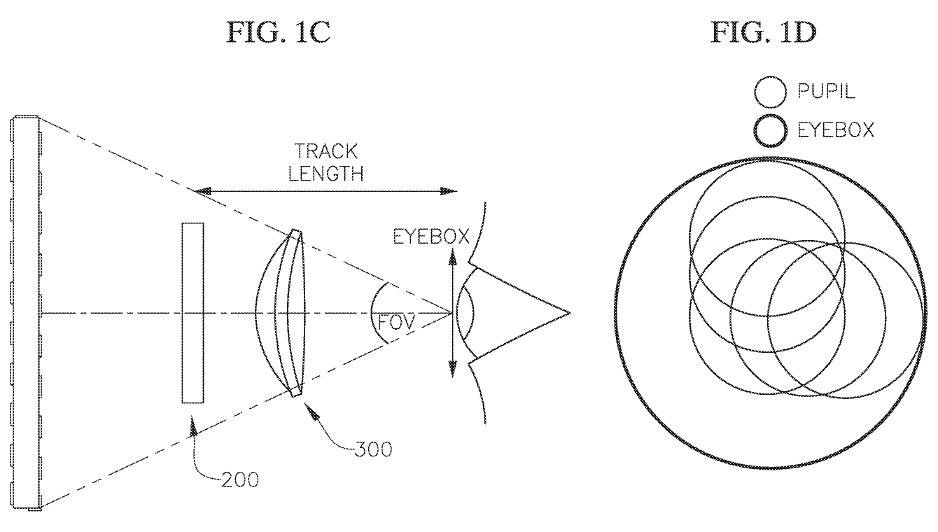

With reference now to FIG. 3, a catadioptric lens system 300’ according to another embodiment of the present disclosure includes a first lens 301’, a second lens 302’, a third lens 303’, a reflective polarizer 304’, and a quarter wave plate 305’. In the illustrated embodiment, the second lens 302’ is between the first lens 301’ and the third lens 303’. Additionally, in the illustrated embodiment, the first lens 301’ includes a first curved surface 306’ facing away from the second lens 302’ and a second curved surface 307’ facing the second lens 302’. In one or more embodiments, the first curved surface 306’ of the first lens 301’ is aspherical and the second curved surface 307’ of the first lens 301’ is spherical.

The second lens 302’ includes a curved surface 308’ facing the first lens 301’ and a flat (or substantially flat) surface 309’ facing away from the first lens 301’ and toward the third lens 303’. In one or more embodiments, the curved surface 308’ of the second lens 302’ is concave and may be aspherical or spherical.

The third lens 303’ includes a flat (or substantially flat) surface 310’ facing the second lens 302’ and a curved surface 311’ facing away from the second lens 302’. In one or more embodiments, the curved surface 311’ of the third lens 303’ is convex and aspherical. Additionally, in one or more embodiments, the catadioptric lens system 300’ includes a half-mirror coating 312’ on the curved surface 311’ of the third lens 303’ and an anti-reflective (AR) coating on the first curved surface 306’ of the first lens 301’, the second curved surface 307’ of the first lens 301’, and the curved surface 308’ of the second lens 302’.

In the illustrated embodiment, the reflective polarizer 304’ is laminated on the second curved surface 307’ of the first lens 301’, and the quarter wave plate 305’ is laminated on the flat (or substantially flat) surface 309’ of the second lens 302’. Accordingly, the reflective polarizer 304’ and the quarter wave plate 305’ are on two different surfaces (e.g., surfaces that face away from each other). Thus, the reflective polarizer 304’ and the quarter wave plate 305’ are separate and separated from each other by the second lens 302’. Providing the reflective polarizer 304’ and the quarter wave plate 305’ on two different surfaces is configured to improve performance and efficiency of the catadioptric lens system 300’. Additionally, in the illustrated embodiment, the first lens 301’ and the second lens 302’ are separate from each other (e.g., the first lens 301’ and the second lens 302’ are not bonded or otherwise connected to each other), and the second lens 302’ and the third lens 303’ are bonded (e.g., glued) to each other.

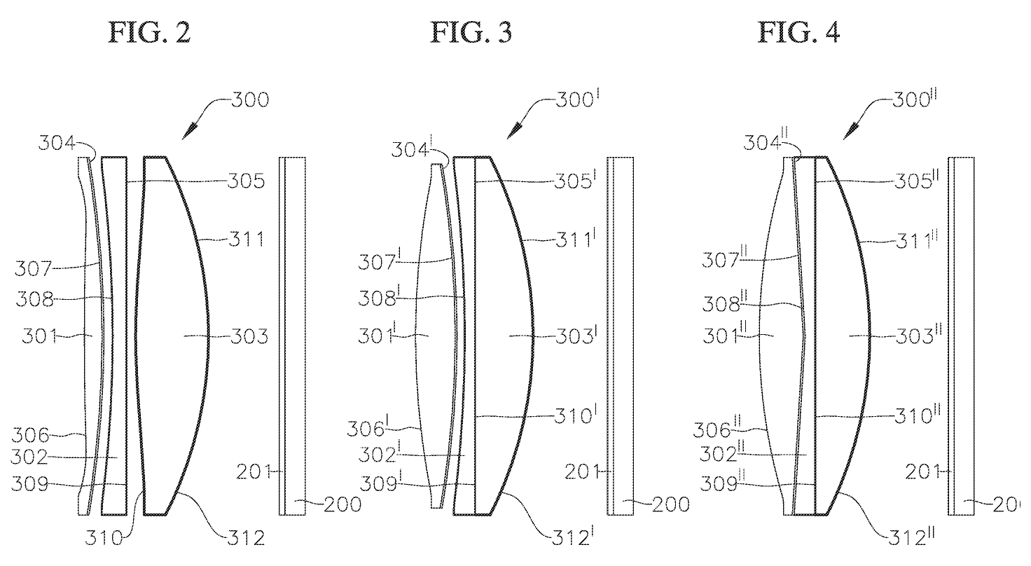

With reference now to FIG. 4, a catadioptric lens system 300’’ according to another embodiment of the present disclosure includes a first lens 301’’, a second lens 302’’, a third lens 303’’, a reflective polarizer 304’’, and a quarter wave plate 305’’. In the illustrated embodiment, the second lens 302’’ is between the first lens 301’’ and the third lens 303’’. Additionally, in the illustrated embodiment, the first lens 301’’ includes a first curved surface 306’’ facing away from the second lens 302’’ and a second curved surface 307’’ facing the second lens 302’’. In one or more embodiments, the first curved surface 306’’ of the first lens 301’’ is convex (e.g., aspherical or spherical) and the second curved surface 307’ of the first lens 301’ is convex and spherical.

The second lens 302’’ includes a curved surface 308’’ facing the first lens 301’’ and a flat (or substantially flat) surface 309’’ facing away from the first lens 301’’ and toward the third lens 303’’. In one or more embodiments, the curved surface 308’’ of the second lens 302’’ is concave and may be spherical. Additionally, in one or more embodiments, the curved surface 308’’ of the second lens 302’’ and the second curved surface 307’’ of the first lens 301’’ may have the same (or substantially the same) radius of curvature.

The third lens 303’’ includes a flat (or substantially flat) surface 310’’ facing the second lens 302’’ and a curved surface 311’’ facing away from the second lens 302’’. In one or more embodiments, the curved surface 311’’ of the third lens 303’’ is convex and aspherical. Additionally, in one or more embodiments, the catadioptric lens system 300’’ includes a half-mirror coating 312’’ on the curved surface 311’’ of the third lens 303’’ and an anti-reflective (AR) coating on the first curved surface 306’ of the first lens 301’.

In the illustrated embodiment, the reflective polarizer 304’’ is laminated on the curved surface 307’’ of the first lens 301’’, and the quarter wave plate 305’’ is laminated on the flat surface 309’’ of the second lens 302’’. Accordingly, the reflective polarizer 304’’ and the quarter wave plate 305’’ are on two different surfaces (e.g., surfaces that face away from each other). Thus, the reflective polarizer 304’’ and the quarter wave plate 305’’ are separate and separated from each other by the second lens 302’’. Providing the reflective polarizer 304’’ and the quarter wave plate 305’’ on two different surfaces is configured to improve performance and efficiency of the catadioptric lens system 300’’. Additionally, in the illustrated embodiment, the first lens 301’’ and the second lens 302’’ are bonded (e.g., glued) to each other and the second lens 302’ and the third lens 303’ are bonded (e.g., glued) to each other.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A catadioptric optical system comprising:
a first lens having a first curved surface and a second curved surface;
a reflective polarizer on the second curved surface of the first lens;
a second lens having a curved surface facing second curved surface of the first lens and a substantially flat surface facing away from the first lens; and
a third lens having a first surface facing the second lens and a second surface facing away from the second lens,
wherein the second lens is between the first lens and the third lens.

2. The catadioptric optical system of claim 1, further comprising a quarter waveplate on the substantially flat surface of the second lens.

3. The catadioptric optical system of claim 1, wherein the first lens, the second lens, and the third lens are separable from each other.

4. The catadioptric optical system of claim 1, wherein the second lens and the third lens are bonded together.

5. The catadioptric optical system of claim 1, wherein the first lens, the second lens, and the third lens are bonded together.

6. The catadioptric optical system of claim 1, wherein the reflective polarizer is laminated to or coated on the first lens.

7. The catadioptric optical system of claim 1, wherein the first surface of the third lens is substantially flat.

8. The catadioptric optical system of claim 1, wherein the first curved surface of the first lens is convex and spherical or aspherical.

9. The catadioptric optical system of claim 8, wherein the curved surface of the second lens is concave and spherical or aspherical.

10. The catadioptric optical system of claim 1, wherein the first surface of the third lens is convex.

11. The catadioptric optical system of claim 1, further comprising a half-mirror coating on the second surface of the third lens facing away from the second lens.

12. The catadioptric optical system of claim 11, further comprising an anti-reflective coating on at least one of the first curved surface of the first lens, the second curved surface of the first lens, the curved surface of the second lens, the substantially flat surface of the second lens, or the first surface of the third lens.

13. A virtual reality headset comprising:
a display;
a processor;
a non-volatile memory device; and
the catadioptric optical system of claim 1.

14. The virtual reality headset of claim 13, further comprising a headband or strap configured to secure the virtual reality headset to a user’s head.

15. The virtual reality headset of claim 13, wherein the display is an organic light emitting display.

16. The virtual reality headset of claim 13, wherein the reflective polarizer and the quarter waveplate are on opposite sides of the second lens.

17. The virtual reality headset of claim 13, wherein the first lens, the second lens, and the third lens are separable from each other.

18. The virtual reality headset of claim 13, wherein the second lens and the third lens are bonded together.

19. The virtual reality headset of claim 13, wherein the first lens, the second lens, and the third lens are bonded together.

20. The virtual reality headset of claim 13, further comprising a circular polarizer on a surface of the display facing the catadioptric optical system.
